(19) United States
(12) Patent Application Publication
(10) Pub. No.: US 2026/0204308 A1
(43) Pub. Date: Jul. 16, 2026

(54) METHODS, SYSTEMS, AND APPARATUSES TO OUTPUT DATA FROM A MEMORY DEVICE

(71) Applicant: Micron Technology, Inc., Boise, ID (US)

(72) Inventor: Woo Hyun Paik, Suwanee, GA (US)

(73) Assignee: Micron Technology, Inc., Boise, ID (US)

(21) Appl. No.: 19/413,144

(22) Filed: Dec. 9, 2025

Related U.S. Application Data
(60) Provisional application No. 63/744,639, filed on Jan. 13, 2025.

(51) Int. Cl. G11C 11/4076; G11C 11/4096; H03K 5/135; H03K 19/20

(52) U.S. Cl. CPC G11C 11/4076; G11C 11/4096; H03K 5/135; H03K 19/20

(57) ABSTRACT

A memory device can include one or more core dies and an interface die. A read clock signal having a first frequency may be generated on the interface die and provided to circuitry on the interface die. The read clock signal is provided from the interface die to the core die(s). Access operations (e.g., read operations) are performed on a memory array on at least one core die based on the read clock signal. The data read from the memory array(s) is provided to the interface die. A data clock signal having a second frequency is generated on the interface die based on the read clock signal. The read data is output from the interface die based on the data clock signal. In some instances, pulses in the data clock signal are aligned with rising and falling edges of the pulses in the read clock signal.

### CROSS-REFERENCE TO RELATED APPLICATION

This application claims the filing benefit of U.S. Provisional Application No. 63/744,639, filed Jan. 13, 2025. This application is incorporated by reference herein in its entirety and for all purposes.

### BACKGROUND

A memory device may be a stacked memory device, in which a number of core dies, each containing a memory array, are stacked on top of an interface die. The interface die may have terminals which connect to one or more external devices. The interface die may communicate with the core dies to perform various operations, such as read or write operations to the memory arrays in one or more of the core dies.

### BRIEF DESCRIPTION OF THE DRAWINGS

FIG. 1 illustrates a block diagram of an example semiconductor device according to an embodiment of the disclosure;

FIG. 2 illustrates a block diagram of an example memory device according to an embodiment of the disclosure;

FIG. 3 illustrates a block diagram of an example memory device showing signal and data flows according to an embodiment of the disclosure;

FIG. 4 illustrates an example timing diagram of the read clock signal and the data clock signal according to an embodiment of the disclosure;

FIG. 5 illustrates a diagram of an example data clock signal generator circuit according to an embodiment of the disclosure;

FIGS. 6A-6C illustrate example timing diagrams for the data clock signal generator circuit shown in FIG. 5 according to an embodiment of the disclosure; and

FIG. 7 illustrates a flowchart of an example method of operating a memory device according to an embodiment of the disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized, and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

A memory device may include a number of core dies with each core die including a memory array. The core dies can be stacked vertically on an interface die, which communicates between external devices and the core dies. During an access operation such as a read or write operation, the interface die may receive a command and addresses that may specify memory cell(s) in one or more of the core dies. In some instances, an even clock signal and an odd clock signal are generated on the interface die. However, the even and odd clock signals may become skewed with respect to each other, which can adversely impact read and write operations.

Embodiments disclosed herein provide a memory device that generates a clock signal on an interface die and uses that clock signal in circuitry on the interface die and for access operations on one or more core dies. The core die(s) may be stacked vertically on the interface die. The clock signal can have one frequency when generated by a clock generator on the interface die and the same or substantially the same frequency when received at an input/output circuit on the interface die. A data clock signal that is based on the clock signal and used by the input/output circuit to output read data has a different (e.g., higher) frequency. For example, the frequency of the data clock signal can be twice the frequency of the clock signal, although other embodiments are not limited to this implementation. In one embodiment, the clock signal is a single clock signal that may eliminate issues regarding skew between signals. Additionally, the single clock signal may reduce the number of signal lines that are used on the interface die, which in turn may reduce line congestion on the interface die.

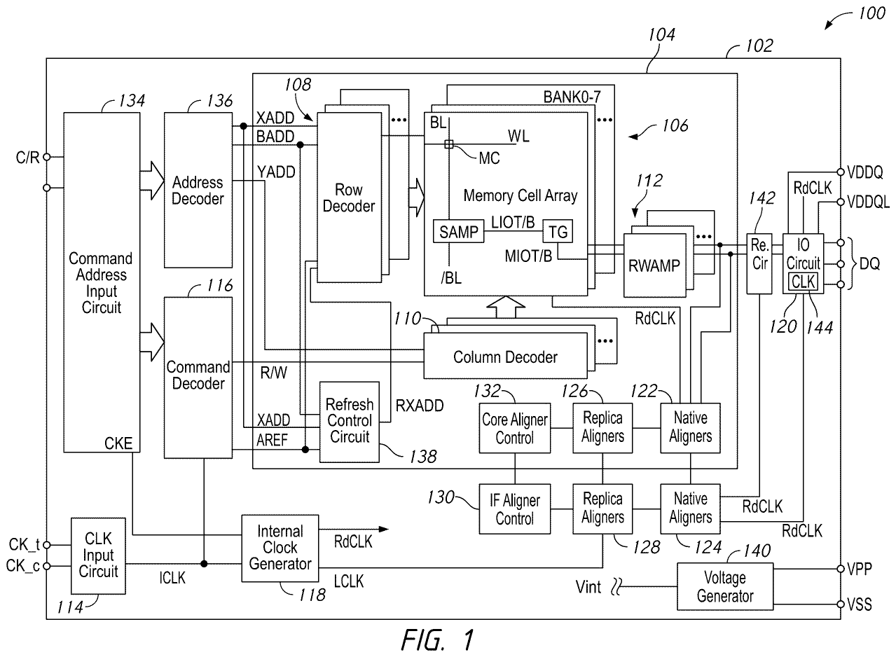

FIG. 1 is a block diagram of an example semiconductor device 100 according to an embodiment of the disclosure. The semiconductor device 100 may be a semiconductor memory device, such as a Dynamic Random-Access Memory (DRAM) device. The DRAM device may include an interface die and a plurality of core dies that are stacked on or over the interface die. In the example diagram of FIG. 1, certain components are shown located on an interface die 102, while other components are shown as part of each of the core dies. For the sake of clarity, only a single core die 104 and its components are shown. However, there may be multiple core dies (e.g., 2, 4, 6, 8, 16, or more) each with similar components to each other. The example semiconductor device 100 of FIG. 1 shows a particular arrangement of components between the interface die 102 and the core die 104, however other arrangements may be used in other embodiments (e.g., the refresh control circuit 138 may be on the interface die 102 in some embodiments). For the sake of illustration, the core die 104 is drawn as a box which is smaller than the interface die 102, however the core die 104 and the interface die 102 may have any size relationship to each other. For example, the core die 104 and the interface die 102 may be approximately the same size.

The semiconductor device 100 includes a memory array 106 on each of the core dies 104. The memory array 106 is shown as including a plurality of memory banks. In the embodiment of FIG. 1, the memory array 106 is shown as including eight memory banks BANK0-BANK7. More or fewer banks may be included in the memory array 106 of other embodiments. Each memory bank includes a plurality of word lines WL, a plurality of bit lines BL and /BL, and a plurality of memory cells MC arranged at intersections of the plurality of word lines WL and the plurality of bit lines BL and /BL. The selection of a word line WL is performed by a row decoder 108 and the selection of the bit lines BL and /BL is performed by a column decoder 110, each of which may also be located on each of the core dies 104. In the embodiment of FIG. 1, the row decoder 108 includes a respective row decoder for each memory bank and the column decoder 110 includes a respective column decoder for each memory bank. The bit lines BL and /BL are coupled to a respective sense amplifier (SAMP) of the memory array 106. Read data from the bit line BL or /BL is amplified by the sense amplifier SAMP and transferred to read/write amplifiers (RWAMP) 112 over complementary local data lines (LIOT/B), transfer gate (TG), and complementary main data lines (MIOT/B) which are coupled to the read/write amplifiers 112. Conversely, write data output from the read/write amplifiers 112 is transferred to the sense amplifier SAMP over the complementary main data lines MIOT/B, the transfer gate TG, and the complementary local data lines LIOT/B, and written in the memory cell MC coupled to the bit line BL or /BL.

The semiconductor device 100 may employ a plurality of external terminals located on the interface die 102 that include column and row command and address (C/R) terminals coupled to a command and address bus to receive commands and addresses, clock terminals to receive clocks CK_t and CK_c, data terminals DQ to provide data (output and input data), and power supply terminals to receive power supply potentials VPP, VSS, VDDQ, and VDDQL.

The clock terminals on the interface die 102 are supplied with external clocks CK_t and CK_c that are provided to a clock (CLK) input circuit 114. The external clocks may be complementary. The clock input circuit 114 generates an internal clock (ICLK) signal based on the CK_t and CK_c clocks. The ICLK clock signal is provided to a command decoder 116 and to an internal clock generator 118. The internal clock generator 118 provides various internal clock LCLK signals based on the ICLK clock signal. The LCLK clock signals may be used for timing operation of various internal circuits. The LCLK clock signals are provided to the input/output circuit 120 to time operation of circuits included in the input/output circuit 120, for example, to data receivers to control the timing of write operations (e.g., to time the receipt of write data) and to latches to control the timing of read operations (e.g., to time the output of read data).

The LCLK clock signals may include a read clock (RdCLK) signal that is used to control the timing of read operations and a write clock signal (not shown) that is used to control the timing of write operations. The RdCLK clock signal may be passed to the input/output circuit 120 and also to other internal components of the interface die 102 and the core dies 104. Different ones of the core dies 104 may have different amounts of time lag (e.g., due to different temperatures of the different core dies, different distances from the interface die 102, etc.).

The semiconductor device 100 can include a native path, which includes native aligners 122 on each of the core die 104 and native aligners 124 on the interface die 102. Each of the core die 104 may have the native aligners 122 along read and write native paths. The native aligners 124 on the interface die 102 receive the LCLK clock signals (e.g., the RdCLK clock signal) and provide a delayed clock to the input/output circuit 120 of the interface die 102. The native aligners 122, 124 include one or more delay circuits that may add a configurable about of delay time to the signals in the core die 104. The amount of delay in the native aligners 122, 124 may be managed to control the timing at which data is provided to the input/output circuit 120. For example, the native aligners 122 may provide a delayed signal that is used to determine when the core die 104 provides the data, and the native aligners 124 can provide a delayed signal that is used to determine when the input/output circuit 120 latches the data provided by the core die 104.

The semiconductor device 100 may also include a replica path, which includes replica aligners 126 in each of the core die 104 and replica aligners 128 in the interface die 102. The replica path may be used to measure the amount of delay in that die to adjust the amount of delay in the native aligners 122, 124. Similar to the native path, the replica path may also include delay circuits that may be adjusted to determine a proper length of delay. The internal clock generator 118 provides an oscillator signal to the replica aligners 128 of the interface die 102 and to the replica aligners 126 of the core die 104. An interface aligner control circuit 130 measures a difference between the delayed oscillator signal from the replica aligners 126, 128 (e.g., with a phase detector) and uses that measured difference to set a delay in the replica aligners 128 and the native aligners 124 of the interface die 102, and instructs a core aligner control circuit 132 to adjust the replica aligners 126 and the native aligners 122 of the core die 104.

The interface aligner control circuit 130 includes a state machine, which may control the behavior of the interface aligner control circuit 130 and the core aligner control circuit 132. For example, different modes may involve adjusting the replica aligners 126, 128 with coarse alignment or fine alignment, and/or the native aligners 122, 124 with coarse or fine alignment. In some embodiments, the interface aligner control circuit 130 includes counters for each of the core die 104. The counters may be used to track when the phase detector for that core die has a same value for a threshold amount of time. The counters may be used to enter the aligner control into one or more counter-based fast alignment (CFAM) mode. For example, the counters may be adjusted during a default maintenance state of the semiconductor device 100. If the phase detector value matches a previous phase detector value, the count value for that die may be changed (e.g., increased). In some embodiments, since averaging may be used, the count value may be increased by an amount which reflects the size of the averaging window. If the phase detector value does not match the previous phase detector value, then the count may be reset.

The C/R terminals may be supplied with memory addresses. The memory addresses supplied to the C/R terminals are transferred, via a command/address input circuit 134, to an address decoder 136. The address decoder 136 receives the address and supplies a decoded row address XADD to the row decoder 108 and supplies a decoded column address YADD to the column decoder 110. The address decoder 136 may also supply a decoded bank address BADD, which may indicate the bank of the memory array 106 containing the decoded row address XADD and column address YADD.

The C/R terminals may be supplied with commands. Example commands include timing commands for controlling the timing of various operations, access commands for accessing the memory, such as read commands for performing read operations and write commands for performing write operations, as well as other commands and operations. The access commands may be associated with one or more row addresses XADD, column addresses YADD, and bank addresses BADD to indicate the memory cell(s) to be accessed.

The commands may be provided as internal command signals to the command decoder 116 via the command/address input circuit 134. The command decoder 116 includes circuits to decode the internal command signals to generate various internal signals and commands for performing operations. For example, the command decoder 116 may provide a row command signal to select a word line and a column command signal to select a bit line.

The semiconductor device 100 may receive an access command that is a read command. When a read command is received, and a bank address, a row address and a column address are timely supplied with an activate command or the read command, read data is read from memory cells in the memory array 106 corresponding to the row address and column address. The read command is received by the command decoder 116, which provides internal commands so that read data from the memory array 106 is provided to the read/write amplifiers 112. The read data may be latched in a core die data latch (not shown) with timing based on the clock signal delayed by the native aligners 122. The read data is received by data latches of the input/output circuit 120 with timing based on a data clock signal provided to the data latches by a clock (CLK) generator 144. The read data is output to outside the semiconductor device 100 from the data terminals DQ via the input/output circuit 120.

The semiconductor device 100 may receive an access command which is a write command. When the write command is received, and a bank address, a row address and a column address are timely supplied with an activate command or the write command, write data is supplied through the DQ terminals to the read/write amplifiers 112. The write data supplied to the data terminals DQ is written to a memory cell in the memory array 106 corresponding to the row address and column address. The write command is received by the command decoder 116, which provides internal commands so that the write data is received by data receivers in the input/output circuit 120. Write clocks may also be provided to the external clock terminals for timing the receipt of the write data by the data receivers of the input/output circuit 120. The write data is supplied to the memory array 106 via the input/output circuit 120 and the read/write amplifiers 112.

The semiconductor device 100 may also receive commands causing it to carry out one or more refresh operations as part of a self-refresh mode. In some embodiments, the self-refresh mode command may be externally issued to the semiconductor device 100. In some embodiments, the self-refresh mode command may be periodically generated by a component of the semiconductor device (e.g., a controller). In some embodiments, when an external signal indicates a self-refresh entry command, the refresh signal AREF may also be activated. The refresh signal AREF may be a pulse signal that is activated when the command decoder 116 receives a signal that indicates entry to the self-refresh mode. The refresh signal AREF may be activated once immediately after command input, and thereafter may be cyclically activated at desired internal timing. The refresh signal AREF may be used to control the timing of refresh operations during the self-refresh mode. Thus, refresh operations may continue automatically. A self-refresh exit command may cause the automatic activation of the refresh signal AREF to stop and return to an IDLE state. The refresh signal AREF is supplied to the refresh control circuit 138. The refresh control circuit 138 supplies a refresh row address RXADD to the row decoder 108, which may refresh one or more wordlines WL indicated by the refresh row address RXADD.

The power supply terminals are supplied with power supply potentials VPP and VSS. The power supply potentials VPP and VSS are supplied to an internal voltage generator circuit 140. The internal voltage generator circuit 140 generates various internal potentials Vint based on the power supply potentials VPP and VSS supplied to the power supply terminals. For example, one internal potential is VDDC that is used in the core die 104.

The power supply terminals are also supplied with power supply potentials VDDQ and VDDQL. The power supply potentials VDDQ and VDDQL are supplied to the input/output circuit 120. The power supply potentials VDDQ and VDDQL supplied to the power supply terminals may be the same potentials as the power supply potentials VPP and VSS supplied to the power supply terminals in an embodiment of the disclosure. The power supply potentials VDDQ and VDDQL supplied to the power supply terminals may be different potentials from the power supply potentials VPP and VSS supplied to the power supply terminals in another embodiment of the disclosure. The power supply potentials VDDQ and VDDQL supplied to the power supply terminals are used for the input/output circuit 120 so that power supply noise generated by the input/output circuit 120 does not propagate to the other circuit blocks.

The RdCLK clock signal is a single clock signal generated by the internal clock generator 118 on the interface die 102 and transmitted to the input/output circuit 120 on the interface die 102. The input/output circuit 120 provides the RdCLK clock signal to a redriver circuit 142 on the interface die 102. The redriver circuit 142 provides the RdCLK clock signal to the native aligner 124, which in turn provides the RdCLK clock signal to the native aligner 122 on the core die 104. The native aligner 122 provides the RdCLK clock signal to the memory array 106 to read data from the memory array 106. The read data and the RdCLK clock signal are provided to the redriver circuit 142, which provides the read data and the RdCLK clock signal to the input/output circuit 120. The read data may be latched in data latches (not shown) in the input/output circuit 120 with timing based on the RdCLK clock signal delayed by the native aligners 122, 124. The clock generator 144 receives the RdCLK clock signal and generates a data clock (DQCLK) signal. The read data is provided to the DQ terminals based on the DQCLK clock signal.

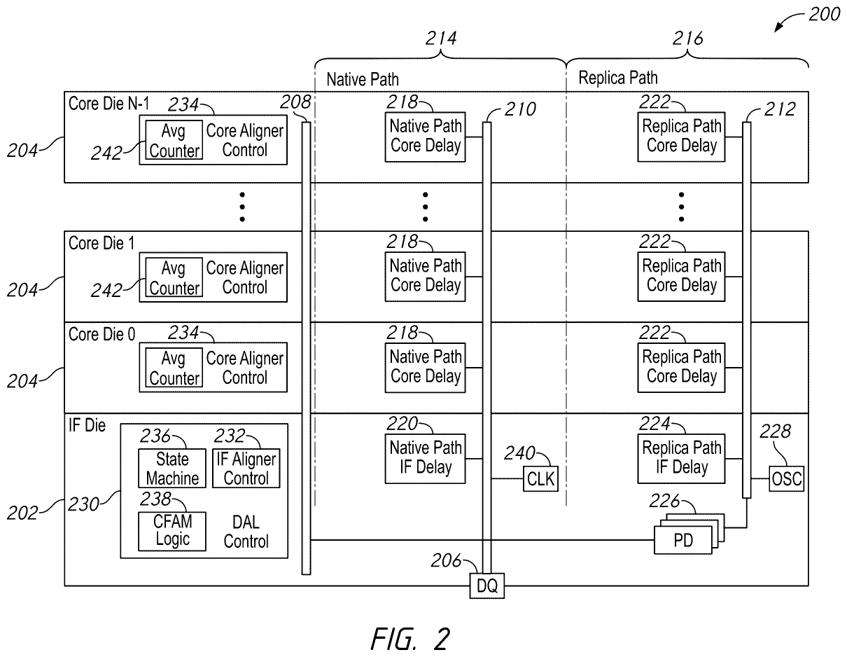

FIG. 2 is a block diagram of an example memory device 200 according to an embodiment of the disclosure. The memory device 200 may, in some embodiments, represent a cross sectional view of a memory device such as the semiconductor device 100 of FIG. 1. The memory device 200 includes an interface (IF) die 202, and a number of core dies 204 that are stacked on the interface die 202. In FIG. 2, the core dies 204 are labelled core die 0 through core die N-1 for a total of N core dies.

The interface die 202 may have a number of terminals to couple the memory device 200 to external devices. For example, the interface die 202 may include terminals such as clock terminals (e.g., terminals CK_t and CK_c of FIG. 1), power terminals (e.g., terminals VPP, VSS, VDDQ, VDDQL of FIG. 1), data terminals DQ 206, command terminals (e.g., terminals C/R of FIG. 1), etc. The core dies 204 may be coupled to the interface die 202 by one or more through silicon vias (TSVs) that may penetrate the stack of core dies 204 and carry commands, signals, and/or data between the core dies 204 and the interface die 202. In FIG. 2, three sets of TSVs are shown, control path TSV 208, native path TSVs 210, and replica path TSVs 212. The TSVs 208, 210, 212 include one or more signal lines that connect the different dies of the memory device 200 to each other. While the control path TSVs 208, the native path TSVs 210 and the replica path TSVs 212 are shown separately, in some embodiments, certain signal lines may be shared between the TSV groups.

In some embodiments, the timing of the data passing between the interface die 202 and the core dies 204 may need to be aligned so that information reaches (and/or is received from) a given core die 204 with predictable timing. Information should reach each core die 204 (or be received from each core die 204) with approximately the same timing (e.g., timing which is within a tolerance of each other). As may be seen, the dies that are higher in the stack (e.g., Core Die N-1) can be further from the interface die 202 than the dies that are lower in the stack (e.g., Core Die 0). In addition, different core dies 204 may have different temperatures, manufacturing variations etc. that may also affect the travel time of information such as signals and data between the core dies 204 and the interface die 202. There may thus be different propagation times between the interface die 202 and different ones of the core dies 204. To prevent misalignment of signals and/or data being conveyed in the memory device 200, aligner circuits may be used to provide adjustable delays along native signal paths 214 in the core dies 204 and the interface die 202. These delays may be adjusted based on measured signal alignment along a replica path 216, which may include circuits that mimic the timing along a native path 214.

The native path 214 may include the native path TSVs 210 that convey information (e.g., signals such as commands and clock signals and data) between the memory arrays of the core dies 204 and the interface die 202. The replica path 216 may include the replica path TSVs 212 and other circuits that mimic an amount of time it takes signals and data to propagate along the native path 214. Both the native path 214 and the replica path 216 may also include variable delay circuits that may be adjusted to align signal and data propagation times between the different core dies 204. For example, the native path 214 includes native path delay circuits 218 on the core dies 204 and native path delay circuits 220 on the interface die 202, while the replica path 216 includes replica path delay circuits 222 on the core dies 204 and replica path delay circuits 224 on the interface die 202. In some embodiments, the native path delay circuits 218 are included in native aligners 122 of FIG. 1 and the native path delay circuits 220 are included in native aligners 124 of FIG. 1. In some embodiments, replica path delay circuits 222 are included in replica aligners 126 of FIG. 1 and the replica path delay circuits 224 are included in replica aligners 128 of FIG. 1. A delay in signal propagation along the replica path 216 may be measured to align delays in the native path 214. For example, the interface die 202 includes a number of phase detector (PD) circuits 226 that measure a difference between an oscillator signal from an oscillator circuit 228 after the oscillator signal propagates through the replica path delay circuits 222 in the core dies 204 and the replica path delay circuits 224 in the interface die 202. The measured phase differences from phase detector circuits 226 are provided to a data aligner control circuit 230 of the interface die 202, which sets delays in the interface die 202 and delays in each of the core dies 204 based on the measured phase differences.

Each of the delay circuits 218, 220, 222, 224 may include one or more variable delay circuits that may be adjusted based on a control circuit. An IF aligner control circuit 232 may control adjustments in the delay circuits 220, 224 of the interface die 202, while core aligner control circuits 234 may control adjustments in the delay circuits 218, 222 of the core dies 204. For the sake of clarity, signal lines have been simplified and/or omitted in FIG. 2 that show how the aligner control circuits 232, 234 are coupled to the delay circuits 218, 220, 222, 224.

The data aligner control circuit 230 includes the interface die aligner control circuit 232, a state machine 236 and CFAM logic 238. The state machine 236 sets a current state of the memory device 200 that determines how the delay values for the native path 214 and the replica path 216 should be adjusted. The interface aligner control circuit 232 sets a delay code that determines a delay in the native path delay circuits 220 and the replica path delay circuits 224 of the interface die 202. The CFAM logic 238 is used to monitor the signals from the phase detectors 226 when the state machine 236 is in a maintenance mode to determine if a fast alignment mode should be entered.

The control TSVs 208 may be used to convey information between the core aligner control circuits 234 in the core dies 204 and the data aligner control circuit 230 in the interface die 202. For example, the control TSVs 208 may be used to convey information such as signals that indicate a state of the state machine 236, identification information that indicates which of the core dies 204 is being adjusted, and/or other related signals.

As shown in the example of FIG. 2, the native path 214 includes data terminals DQ 206, which are coupled to memory arrays in the core dies 204 by the native path TSVs 210. The native path TSVs 210 also distribute clock signals from a clock circuit 240, which may generate internal clock signals based on an external clock (not shown). In some embodiments, the clock circuit 240 is included in the internal clock generator 118 of FIG. 1. The clock signals provided by the clock circuit 240 may control the timing of operations between the interface die 202 and the core dies 204. The replica path 216 may include the replica path TSVs 212 that provide an oscillator signal from the oscillator circuit 228 of the interface die 202 to the replica path delay circuits 222 of the core dies 204. The oscillator signal may be passed through one or more replica path delay circuits 222, 224. The state machine 236 may adjust the delays in the replica path delay circuits 222, 224 of the replica path 216 and measure an alignment of the oscillator signal. Based on the values in the replica path 216 that bring alignment, the delay values in the native path 214 may also be adjusted. For example, the delay values may be matched between the native and the replica paths 214, 216.

In an example read operation, data may be passed along the TSVs 210 from one or more selected ones of the core dies 204 and provided at the DQ terminal 206. The clock circuit 240 may provide the RdCLK clock signal, which may be adjusted by the native path delay circuit 220 to provide a delayed interface read clock signal. The delayed interface read clock signal may be used to determine the timing with which the read data is provided from the selected one(s) of the core dies 204 along the TSVs 210 to the DQ terminal 206. The read clock signal may also be passed along the TSVs 210 to the native path core delay circuits 218 in the selected one(s) of the core dies 204, which may provide core delayed read clock signal(s). The core delayed read clock signals may determine the timing with which the data is received at an input/output circuit (e.g., input/output circuit 120 of FIG. 1). Based on the propagation of the oscillator signal OSC from the oscillator circuit 228, the state machine 236 may adjust the delays in the native path 214 to ensure that the read data reaches the input/output circuit in alignment with the RdCLK clock signal.

The data aligner control circuit 230 on the interface die 202 operates control circuits 232 and 234 in the interface 202 die and the core dies 204, respectively. The control circuits 232 and 234 may adjust delays in replica path delay circuits 222 and 224 of their respective dies. The state machine 236 may control which circuits and which delays are being adjusted and monitor the measured alignments. The delays set in the replica path 216 may also be applied to the delay circuits 218 and 220 in the native path 214. Once the measured alignments are within tolerances, the delays may bring the memory device 200 into timing alignment. Each of the core dies 204 and the interface die 202 may have different delays from each other.

The state machine 236 may update the delay values as part of an ongoing process in the memory device 200. For example, the state machine 236 may use an initial set of states to establish delays in the interface aligner control circuit 232 and in each of the core aligner control circuits 234. After the initial states, the state machine 236 may operate a maintenance mode which keeps the delays in alignment. The state machine 236 may enter a default maintenance state after the initialization. To prevent unnecessary adjustment, the default maintenance state may use averaging to determine when a delay value has shifted out of alignment. Each of the core aligner control circuits 234 includes an averaging counter 242 used to average signals from the respective phase detector 226 over time.

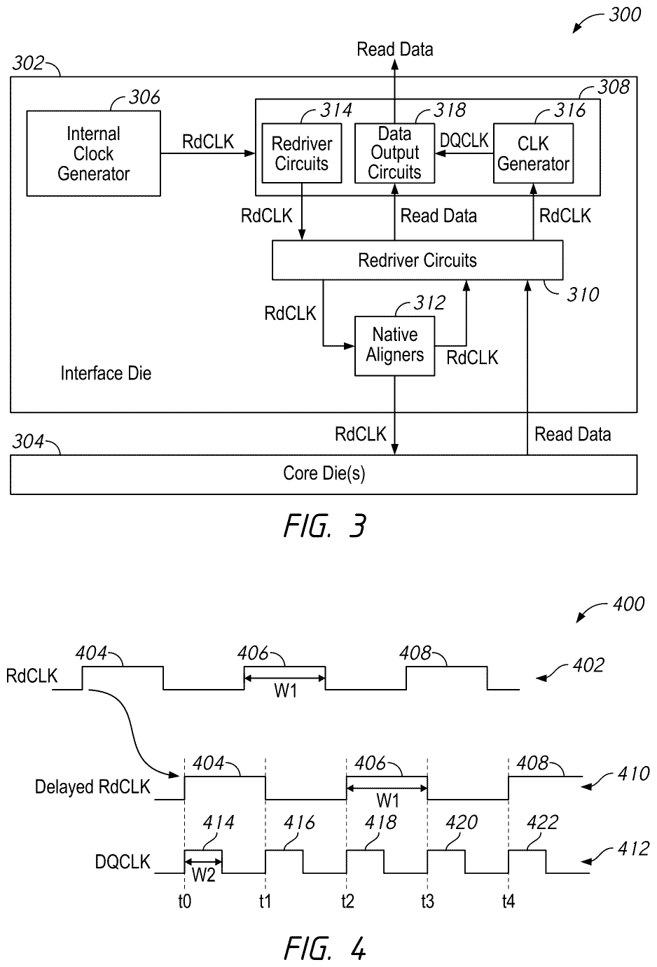

FIG. 3 illustrates a block diagram of an example memory device 300 showing signal and data flows according to an embodiment of the disclosure. The memory device 300 includes an interface die 302 and one or more core dies 304. The interface die 302 can include an internal clock generator 306, an input/output circuit 308, one or more redriver circuits 310, and native aligners 312. In an embodiment, the internal clock generator 306, the input/output circuit 308, the one or more redriver circuits 310, and the native aligners 312 may be implemented as the internal clock generator 118, the input/output circuit 120, the redriver circuit 142, and the native aligners 124 shown in FIG. 1, respectively.

The internal clock generator 306 generates the read clock (RdCLK) signal that is received at the input/output circuit 308. One or more redriver circuits 314 in the input/output circuit 308 receive the RdCLK clock signal and transmit the RdCLK clock signal to the redriver circuit(s) 310. The one or more redriver circuits 314 and the one or more redriver circuits 310 can each include one or more buffer circuits. In one embodiment, the internal clock generator 306 generates the RdCLK clock signal as a single clock signal that is received by the redriver circuit(s) 314 and the redriver circuit(s) 310.

The redriver circuit(s) 310 transmit the RdCLK clock signal to the native aligners 312. The native aligners 312 provide the RdCLK clock signal or a delayed RdCLK clock signal to the one or more core die(s) 304. In one embodiment, the native aligners 312 include one or more delay circuits that can add a configurable about of delay time to the RdCLK clock signal. Data is read out of at least one memory array based on the (delayed) RdCLK clock signal. In one embodiment, the RdCLK clock signal is a single clock signal that is transmitted to the native aligners 312 and the core die(s) 304.

The read data is provided from at least one core die 304 to the one or more redriver circuits 310. The native aligners 312 provide the RdCLK clock signal or a delayed RdCLK clock signal to the redriver circuit(s) 310. The delayed RdCLK clock signal provided to the redriver circuit(s) 310 may have the same or a different amount of delay as the delayed RdCLK clock signal that can be provided to the core die(s) 304. In one embodiment, the delayed RdCLK clock signal is a single clock signal that is received at the one or more redriver circuits 310.

The redriver circuit(s) 310 transmit the read data and the RdCLK clock signal to the input/output circuit 308. A clock (CLK) generator 316 in the input/output circuit 308 receives the RdCLK clock signal, and based on the RdCLK signal, provides a data clock (DQCLK) signal to one or more data output circuits 318 in the input/output circuit 308. In one embodiment, the RdCLK clock signal received at the input/output circuit 308 and used to provide the DQCLK clock signal is a single clock signal. Additionally, the RdCLK clock signal has a frequency n and a frequency of the DQCLK clock signal is a multiple of n (i.e., Mn), where M is a number greater than zero. In one embodiment, the data output circuit(s) 318 include data latches to latch the read data.

The one or more data output circuits 318 also receive the read data from the redriver circuit(s) 310. The data output circuit(s) 318 output the read data based on the DQCLK clock signal. In one embodiment, the read data is output to external data terminals on the interface die 302, such as the DQ terminals shown in FIG. 1.

In some embodiments, the RdCLK clock signal can be a single clock signal that is provided to circuitry on the interface die 302 and to circuitry on the core die(s) 304. For example, in FIG. 3, the clock signal RdCLK is provided by the internal clock generator 306 to the input/output circuit 308, which in turn provides the clock signal RdCLK to the one or more redriver circuits 310. The redriver circuit(s) 310 provide the clock signal RdCLK to the native aligners 312, which in turn provide the clock signal RdCLK (which may be a delayed clock signal) to the one or more core dies 304. The native aligners 312 also provide the clock signal RdCLK (which may be a delayed clock signal) back to the redriver circuit(s) 310. The one or more redriver circuits 310 provide the clock signal RdCLK back to the input/output circuit 308. The input/output circuit 308 uses the clock signal RdCLK to generate the data clock signal DQCLK to output the read data from the input/output circuit 308. As discussed previously, in embodiments where the clock signal RdCLK is a single clock signal, the single clock signal may avoid issues relating to signal skew between signals, such as even and odd clock signals. Additionally, the single clock signal can reduce the number of signal lines that are used on the interface die, which in turn may reduce line congestion on the interface die.

Although FIGS. 1 through 3 illustrate certain components located within other components, other embodiments are not limited to this implementation. For example, FIG. 1 shows the redriver circuit 142 external to, and connected to the input/output circuit 120. In other embodiments, the redriver circuit 142 can be included with the input/output circuit 120. Additionally, or alternatively, FIG. 3 shows the clock generator 316 within the input/output circuit 308. The clock generator 316 may be external to and connected to the input/output circuit 308 in other embodiments. In some instances, the redriver circuit(s) 314 and the redriver circuit(s) 310 may be implemented together and located within or external to the input/output circuit 308.

FIG. 4 illustrates an example timing diagram 400 of the read clock signal RdCLK and the data clock signal DQCLK according to an embodiment of the disclosure. The RdCLK clock signal is depicted in the waveform 402. The RdCLK clock signal has a frequency n, a pulse width W1, and includes pulses 404, 406, 408. As described earlier, native aligners can provide adjustable delays in the RdCLK clock signal in the core die(s) and the interface die. For example, in FIG. 3, the native aligners 312 may provide one delay in the RdCLK clock signal provided to the core die(s) 304 and another delay in the RdCLK clock signal provided to the one or more redriver circuits 310.

The waveform 410 shows a delayed RdCLK clock signal. The delayed RdCLK clock signal has the frequency n (or substantially the frequency n), the pulse width W1, and includes the pulses 404, 406, 408. In the embodiment shown in FIG. 3, the delayed clock signal can be received by the clock generator 316 in the input/output circuit 308. The clock generator 316 outputs the DQCLK clock signal based on the RdCLK clock signal.

The waveform 412 depicts the DQCLK signal with pulses 414, 416, 418, 420, 422. The DQCLK signal has a frequency Mn (M multiplied by n) and a pulse width W2, where M is a number greater than zero. The frequency Mn can be higher or lower than the frequency n. In the illustrated embodiment, the frequency Mn is equal to 2n (M=2 ). Additionally, or alternatively, the pulse width W2 may be greater or less than W1. In the embodiment of FIG. 4, W2 is less than W1 (e.g., half of W1).

In one embodiment, the DQCLK clock signal is generated such that the rising edges of the consecutive pulses 414, 416, 418, 420, 422 in the DQCLK clock signal are selectively aligned with the rising edges or the falling edges of the pulses 404, 406, 408 in the RdCLK clock signal. For example, at time t0, a rising edge of the pulse 414 in the DQCLK clock signal aligns with a rising edge of the pulse 404 in the RdCLK clock signal. At time t1, a rising edge of the successive or next pulse 416 in the DQCLK clock signal aligns with a trailing or falling edge of the pulse 404. Thus, the rising edges of two successive pulses in the DQCLK clock signal (i.e., pulses 414 and 416) align with the rising and falling edges of a pulse in the RdCLK clock signal (i.e., pulse 404).

At time t2, a rising edge of the next consecutive pulse 418 in the DQCLK clock signal aligns with a rising edge of the consecutive or next pulse 406 in the RdCLK clock signal. At time t3, a rising edge of the successive or next pulse 420 in the DQCLK clock signal aligns with a falling edge of the pulse 406. Again, the rising edges of two successive pulses in the DQCLK clock signal (i.e., pulses 418 and 420) align with the rising and falling edges of a pulse (i.e., pulse 406) in the RdCLK clock signal. At time t4, a rising of the next consecutive pulse 422 in the DQCLK clock signal is aligned with a rising edge of the consecutive or next pulse 408 in the RdCLK clock signal.

In FIG. 4, the pulses 404, 406, 408 in the RdCLK clock signal are successive pulses, but other embodiments are not limited to this configuration. The pulses 414, 416, 418, 420, 422 in the DQCLK clock signal can be aligned with non-successive pulses in the RdCLK clock signal in other embodiments.

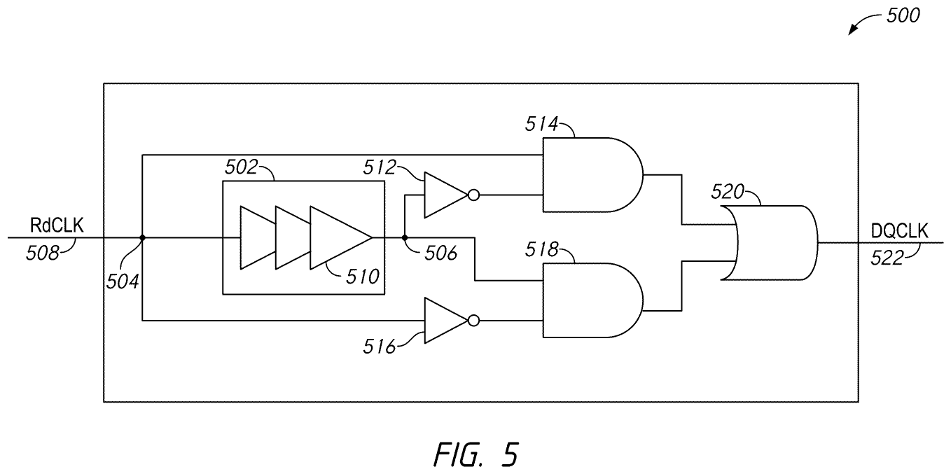

FIG. 5 illustrates a diagram of a data clock signal generator circuit 500 according to an embodiment of the disclosure. In one embodiment, the data clock signal generator circuit 500 is implemented as the clock generator 316 shown in FIG. 3. The data clock signal generator circuit 500 includes a delay circuit 502 connected between a node 504 and a node 506. The RdCLK clock signal is received by the delay circuit 502 on signal line 508. In the illustrated embodiment, the delay circuit 502 includes one or more buffer circuits 510.

An input of an inverter circuit 512 is connected to the node 506 and an output of the inverter circuit 512 is connected to a first input of an AND gate 514. A second input of the AND gate 514 is connected to the node 504. An input of an inverter circuit 516 is connected to the node 504 and an output of the inverter circuit 516 is connected to a first input of an AND gate 518. The second input of the AND gate 518 is connected to the node 506. An output of the AND gate 514 is connected to a first input of an OR gate 520. An output of the AND gate 518 is connected to a second input of the OR gate 520. The DQCLK clock signal is output from the OR gate 520 on signal line 522.

The RdCLK clock signal and the DQCLK clock signal comprise a series of pulses. The data clock signal generator circuit 500 is configured to output the DQCLK clock signal having pulses that align with the edges of the pulses in the RdCLK clock signal. In one embodiment, a rising edge of a pulse in the DQCLK clock signal is aligned with a rising edge of a pulse in the RdCLK clock signal and a rising edge of a successive pulse in the DQCLK clock signal is aligned with a falling edge of the same pulse in the RdCLK clock signal.

Additionally, a frequency of the DQCLK clock signal output on the signal line 522 differs from the frequency of the RdCLK clock signal received on the signal line 508. The frequency of the DQCLK clock signal may be higher or lower than the frequency of the RdCLK clock signal. In one embodiment, the frequency of the DQCLK clock signal is higher than the frequency of the RdCLK clock signal. For example, the frequency of the DQCLK clock is can be twice the frequency of the RdCLK clock signal. Further, in some embodiments, the pulse widths of the pulses in the DQCLK clock signal differ from the pulse widths of the pulses in the RdCLK clock signal.

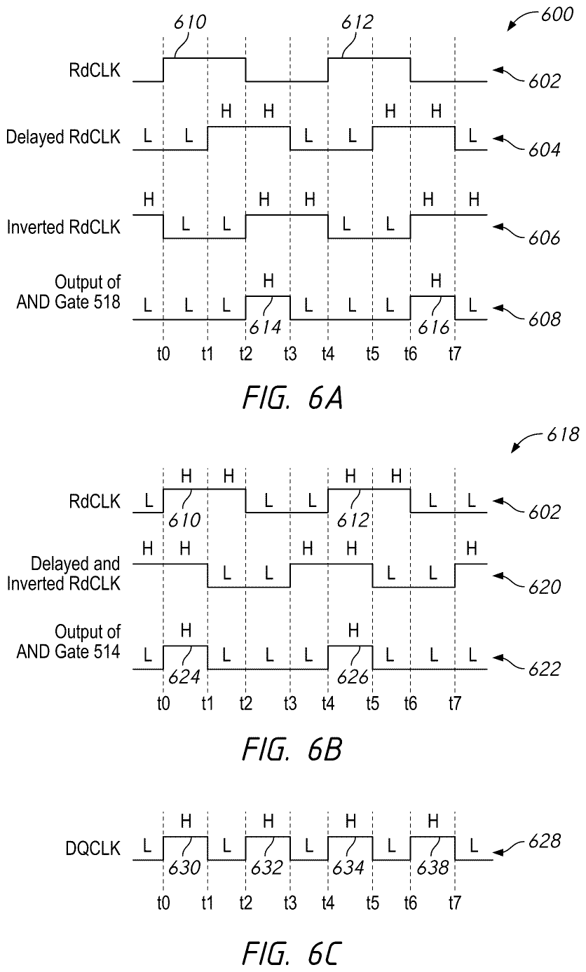

FIGS. 6A-6C illustrate example timing diagrams for the data clock signal generator circuit 500 shown in FIG. 5 according to an embodiment of the disclosure. The timing diagram 600 shown in FIG. 6A depicts the waveforms 602, 604, 606 that produce the waveform 608 at the output of the AND gate 518 (FIG. 5). The waveforms 602, 604, 606, 608 illustrate signal levels of high H (e.g., a “1”) and signal levels of low L (e.g., a “0”).

The waveform 602 includes pulses 610, 612 in the RdCLK clock signal as received by the delay circuit 502. The waveform 604 depicts the delayed RdCLK clock signal at the node 506. The waveform 606 illustrates the inverted RdCLK clock signal at the output of the inverter circuit 516. The signals associated with the waveform 604 (the delayed RdCLK clock signal) and the waveform 606 (the inverted RdCLK clock signal) are input into the AND gate 518. The signal associated with the waveform 608 includes pulses 614, 616. The signal associated with the waveform 608 is output from the AND gate 518.

The timing diagram 618 shown in FIG. 6B depicts the waveforms 602, 620 that produce the waveform 622 at the output of the AND gate 514 (FIG. 5). The waveforms 602, 620, 622 illustrate signal levels of high H (e.g., a “1”) and signal levels of low L (e.g., a “0”). The waveform 602 includes the pulses 610, 612 in the RdCLK clock signal as received by the delay circuit 502. The waveform 620 depicts the delayed and inverted RdCLK clock signal at the output of the inverter circuit 512. The signals associated with the waveform 602 and the waveform 620 are input into the AND gate 514. The signal associated with the waveform 622 includes pulses 624, 626. The signal associated with the waveform 622 is output from the AND gate 514.

FIG. 6C illustrates a waveform 628 that is associated with the DQCLK clock signal output from the OR gate 520 on the signal line 522 (FIG. 5). A signal associated with the waveform 628 is produced by inputting the signal associated with the waveform 608 and the signal associated with the waveform 622 into the OR gate 520. As shown in FIG. 6C, a rising edge of the pulse 610 in the RdCLK clock signal and a rising edge of the pulse 630 in the DQCLK clock signal occur at time t0. Thus, the rising edge of the pulse 630 in the DQCLK signal is aligned with the rising edge of the pulse 610 in the RdCLK clock signal.

A falling edge of the pulse 630 in the DQCLK signal occurs at time t1. At time t2, a falling edge of the pulse 610 in the RdCLK clock signal and a rising edge of the successive or next pulse 632 in the DQCLK clock signal occur. Thus, the rising edge of the pulse 632 in the DQCLK signal is aligned with the falling edge of the pulse 610 in the RdCLK clock signal.

A falling edge of the pulse 632 in the DQCLK signal occurs at time t3. At time t4, a rising edge of the consecutive or next pulse 612 in the RdCLK clock signal and a rising edge of the successive or next pulse 634 in the DQCLK clock signal occur. Thus, the rising edge of the pulse 634 in the DQCLK signal is aligned with the rising edge of the pulse 612 in the RdCLK clock signal.

A falling edge of the pulse 634 in the DQCLK signal occurs at time t5. At time t6, a falling edge of the pulse 612 in the RdCLK clock signal and a rising edge of the successive or next pulse 638 in the DQCLK clock signal occur. Thus, the rising edge of the pulse 638 in the DQCLK signal is aligned with the falling edge of the pulse 612 in the RdCLK clock signal. A falling edge of the pulse 638 in the DQCLK signal occurs at time t7.

The pulse widths of the pulses in the signal associated with the waveform 628 and a frequency of the signal associated with the waveform 628 differ from the pulse widths of the pulses in the signal associated with the waveform 602 and a frequency of the signal associated with the waveform 602. As shown in FIGS. 6B and 6C, the frequency of the signal associated with the waveform 628 is higher (e.g., twice) the frequency of the signal associated with the waveform 602 and the pulse widths of the pulses in the signal associated with the waveform 628 are shorter than the pulse widths of the pulses in the of the signal associated with the waveform 602.

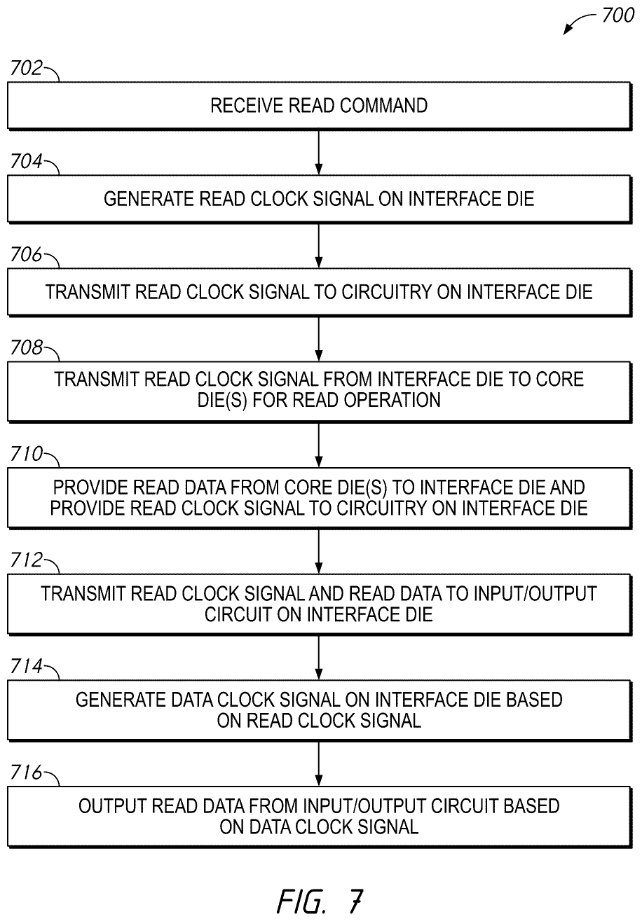

FIG. 7 illustrates a flowchart of an example method 700 of operating a memory device according to an embodiment of the disclosure. Initially, as shown in block 702, a read command is received. The read command may be transmitted by a controller to the memory device. A command/address input circuit, such as the command/address input circuit 134 shown in FIG. 1, can receive the read command.

At block 704, a read clock signal (RdCLK) having a frequency n is generated on an interface die of the memory device. As discussed earlier, the read clock signal (RdCLK) is a single clock signal in one embodiment. At block 706, the read clock signal (RdCLK) is transmitted to circuitry on the interface die. For example, in the embodiment shown in FIG. 3, the read clock signal (RdCLK) is transmitted to the input/output circuit 308, the redriver circuit(s) 310, and the native aligners 312 on the interface die 302.

At block 708, the read clock signal (RdCLK) is transmitted from the interface die to one or more core dies in the memory device for a read operation that is to be performed based on the read command received at block 702. Data is read out of at least one memory array on a core die based on the read clock signal (RdCLK). For example, in the embodiment shown in FIG. 3, the read clock signal (RdCLK) is transmitted from the native aligners 312 on the interface die 302 to the one or more core dies 304.

At block 710, the read data is transmitted from the core die(s) to the interface die and the read clock signal (RdCLK) is transmitted to circuitry on the interface die. At block 712, the read clock signal (RdCLK) and the read data are provided to the input/output circuit on the interface die. In one embodiment, the read clock signal (RdCLK) received at the interface die at block 710 and received at the input/output circuit is a single clock signal having the frequency n. For example, in the embodiment shown in FIG. 3, the read data is provided to the one or more redriver circuits 310 on the interface die from the core die(s) 304 and the single read clock signal (RdCLK) is provided from the native aligners 312 to the redriver circuit(s) 310. The redriver circuit(s) 310 provide the read data and the single read clock signal (RdCLK) to the input/output circuit 308 on the interface die 302.

At block 714, a data clock signal (DQCLK) having a frequency Mn is generated based on the read clock signal (RdCLK), where M is a number greater than zero. In one embodiment, M is equal to two (2) such that the frequency of the data clock signal (DQCLK) is twice the frequency of the read clock signal (RdCLK). For example, in the embodiments shown in FIGS. 3 and 4, the input/output circuit 308 outputs the data clock signal (DQCLK) based on the single read clock signal (RdCLK), where the frequency of the data clock signal (DQCLK) is twice the frequency of the read clock signal (RdCLK). Additionally, as shown in FIG. 4, the rising edges of consecutive pulses in the data clock signal (DQCLK) are aligned with the rising and falling edges of consecutive pulses in the read clock signal (RdCLK). In the example embodiment shown in FIG. 3, the clock generator 316 receives the read clock signal (RdCLK) and outputs the data clock signal (DQCLK).

At block 716, the read data is output from the input/output circuit on the interface die based on the data clock signal (DQCLK). For example, in the embodiment shown in FIG. 3, the read data is output from the data output circuit(s) 318 in the input/output circuit 308 based on the data clock signal (DQCLK). The read data can be provided to external data terminals on the interface die, such as the DQ terminals shown in FIG. 1.

The foregoing description, for purposes of explanation, uses specific nomenclature to provide a thorough understanding of the described embodiments. However, it will be apparent to one skilled in the art that the specific details are not required to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art that many modifications and variations are possible in view of the above teachings.

What is claimed is:

1. An apparatus, comprising:
a core die stacked vertically with an interface die, the interface die comprising:
a first clock generator configured to provide a read clock signal, the read clock signal comprising a first pulse; and
a second clock generator configured to receive the read clock signal and provide a data clock signal, the data clock signal comprising a second pulse that aligns with a rising edge of the first pulse and a third pulse that aligns with a falling edge of the first pulse, wherein a frequency of the data clock signal is higher than a frequency of the read clock signal; and
an input/output circuit that receives the data clock signal and outputs data based on the data clock signal.

2. The apparatus of claim 1, wherein the interface die further comprises a redriver circuit that receives the read clock signal from the first clock generator.

3. The apparatus of claim 2, wherein the read clock signal is provided to the core die to provision the data from the core die to the redriver circuit.

4. The apparatus of claim 3, wherein:
the redriver circuit provides the read clock signal and the data to the input/output circuit;
the read clock signal received at the input/output circuit s a single clock signal; and
the interface die further comprises an aligner circuit configured to receive the read clock signal from the redriver circuit and align a timing of the data received from the core die.

5. The apparatus of claim 1, wherein the read clock signal is a single clock signal.

6. The apparatus of claim 1, wherein the second clock generator is included in the input/output circuit.

7. The apparatus of claim 1, wherein the frequency of the data clock signal is twice the frequency of the read clock signal.

8. The apparatus of claim 1, wherein the core die comprises a memory array configured to store the data.

9. The apparatus of claim 1, wherein the second clock generator comprises:
a delay circuit configured to receive the read clock signal;
a first inverter circuit connected to an output of the delay circuit;
a first AND circuit comprising a first input configured to receive the read clock signal and a second input connected to an output of the first inverter circuit;
a second inverter circuit configured to receive the read clock signal;
a second AND circuit comprising a first input connected to the output of the delay circuit and a second input connected to an output of the second inverter circuit; and
an OR circuit comprising a first input connected to an output of the first AND circuit and a second input connected to an output of the second AND circuit.

10. A memory device, comprising:
a core die, comprising a memory array configured to store data;
an interface die stacked vertically with the core die, the interface die comprising:
a first clock generator circuit configured to provide a read clock signal;
an aligner circuit configured to receive the read clock signal and align read data read from the memory array; and
a second clock generator circuit configured to receive the read clock signal and provide a data clock signal having pulses aligned with rising edges and falling edges of pulses in the read clock signal, wherein a frequency of the data clock signal is higher than a frequency of the read clock signal.

11. The memory device of claim 10, wherein the interface die further comprises an input/output circuit configured to receive the read data and the data clock signal and provide the read data to data terminals based on the data clock signal.

12. The memory device of claim 11, wherein the interface die further comprises a redriver circuit configured to receive the read clock signal and provide the read clock signal to the aligner circuit.

13. The memory device of claim 12, wherein the input/output circuit is configured to receive the read clock signal and provide the read clock signal to the redriver circuit.

14. The memory device of claim 13, wherein the aligner circuit is configured to provide the read clock signal as a delayed read clock signal to the core die to read data from the memory array.

15. The memory device of claim 14, wherein the redriver circuit is configured to receive the read clock signal from the aligner circuit as a delayed read clock signal and to receive the read data from the core die and provide the delayed read clock signal to the second clock generator and the read data to the input/output circuit.

16. The memory device of claim 10, wherein the read clock signal is a single read clock signal.

17. The memory device of claim 10, wherein the core die is one of a plurality of core dies stacked vertically.

18. The memory device of claim 10, wherein the second clock generator circuit comprises:
a delay circuit configured to receive the clock signal;
a first inverter circuit connected to an output of the delay circuit;
a first AND circuit comprising a first input configured to receive the clock signal and a second input connected to an output of the first inverter circuit;
a second inverter circuit configured to receive the clock signal;
a second AND circuit comprising a first input connected to the output of the delay circuit and a second input connected to an output of the second inverter circuit; and
an OR circuit comprising a first input connected to an output of the first AND circuit and a second input connected to an output of the second AND circuit.

19. A method, comprising:
receiving a read command to read data from a memory array on a core die;
generating, on an interface die stacked vertically with the core die, a read clock signal having a first frequency;
providing the read clock signal to circuitry on the interface die prior to providing the read clock signal to the core die;
receiving, from the core die at the interface die, the read clock signal and read data read from the memory array based on the read clock signal;
generating, on the interface die, a data clock signal based on the read clock signal, the data clock signal having a second frequency that is higher than the first frequency; and
providing the read data to data terminals on the interface die based on the data clock signal.

20. The method of claim 19, wherein:
the read clock signal comprises first pulses;
the data clock signal comprises second pulses and third pulses;
rising edges of the second pulses align with rising edges of the first pulses in the read clock signal; and
rising edges of the third pulses align with falling edges of the first pulses in the read clock signal.
